(19) United States
(12) Patent Application Publication
(10) Pub. No.: US 2005/0047627 A1
(43) Pub. Date: Mar. 3, 2005

(54) Method and apparatus for encoding and decoding digital representations of works

(75) Inventor: Larry Forsgren, Bagarmossen (SE)

Correspondence Address: SUGHRUE MION, PLLC, 2100 PENNSYLVANIA AVENUE, N.W., SUITE 800, WASHINGTON, DC, 20037, US

(73) Assignee: USTRA FOUNDATION

(21) Appl. No.: 10/652,317

(22) Filed: Sep. 2, 2003

(51) Int. Cl. G06T 9/00; H03M 7/00; H03M 7/30; G10L 19/00; G10L 21/00; G06T 7/00

(52) U.S. Cl. 382/100; 382/232; 341/51; 386/94; 386/112; 704/500

(57) ABSTRACT

A method of encoding digital representations of works comprises the following steps: providing a digital representation of a work, and removing pieces of information from said digital representation in a predetermined pattern. The method provides for an identification of digital representations which is virtually impossible to locate and remove. In a particularly preferred embodiment, the predetermined pattern is repeated, making removal thereof from an illegal copy virtually impossible. A method for decoding digital representations of works and apparatuses for performing encoding and decoding of digital representations of works are also provided.

### FIELD OF INVENTION

The present invention relates generally to the field of protecting copyrighted digital works from piracy and more specifically to a method and an apparatus for rendering works unique in such a way that each and any digital representation treated in accordance with the invention may be identified as to its source, legitimate recipient, or any other information vital to the rights protection of the digital work in question.

### BACKGROUND

Digital representations, of which musical works or video information are examples, commonly rely on a number of known algorithms and methods which compress the information content in order to reduce the need for digital storage space or transmission bandwidth. Such representations are commonly converted from analogue to digital (binary) form by a method of sampling the original wave forms at a rate which is sufficiently higher than the wave forms being imaged. Simplified the techniques being used are based on the same principle as when statistical points are plotted on a chart and are later bound together forming a curve representing a trend. Waves of audio or video information which are very closely related in time, such as adjacent sampling points are considered to be neighbors in amplitude, being part of a trend going up or going down. This way the sampling frequency itself determines the amount of accuracy or fidelity compared to the unbroken analogue wave form. A digital sampling thus has a built in potential loss of information which may or may not be detectable when the information later is retrieved. A state of transparency is aimed at, which ideally means that a perfect copy of the original analogue data should be possible to retrieve after digital encoding and decoding.

To give further examples, the sampling frequency being used in Compact Disc recordings is 44.1 kHz. Roughly that gives a potential of retrieving 20 kHz per channel in a stereo recording which is an approximate upper limit of what a person with perfect hearing can perceive. Digitally distributing music at this rate with 16 bits per sample requires a bandwidth of almost 1.5 megabits per second and it is therefore often desirable and needed to reduce the bandwidth requirement by further compression. The currently most popular format is MP3 which uses a psychoacoustic model for its compression. The psychoacoustic part of the compression relies on algorithms that discard information which it is considered that the human ear cannot hear anyway and which therefore in reality is extraneous information. An example is a tiny sound which occurs at or in the immediate proximity of a very strong sound. The human ear will have difficulty distinguishing the faint sound while being blocked or distracted by the much stronger sound, such as hearing a needle fall while the burglar alarm siren is on to give an extreme example.

Similar techniques are applied in case of visual materials, in order to remove information that the human eye cannot adjust to such as weak reflections of surrounding objects in front of a sunlit background.

After the step of removing such information, a further compression step is usually applied which may or may not consist of lossless compression such as the use of Huffman tables to avoid that repeating patterns in the information consumes bandwidth unnecessarily.

In a number of existing patents protection is attempted to be done before as well as after the distribution of materials. Methods of protection before distribution may involve encryption of the material in such a way that only persons who are in the possession of specific digital keys or special hardware equipment can access the material. Protection of copyrighted material after distribution may entail methods and equipment in order to coerce potential transgressors not to engage in illegal copying or redistribution by introducing potential discovery.

One such method is described in U.S. Pat. No. 6,330,672 to David Hilton Shur issued in 2001, a method for water-marking digital bit streams. The referenced patent relies on various principles of superimposing or integrating decipherable signals or marks which can later serve to identify the work in question or the individual behind illegal redistribution.

In any digital transmission, whether it concerns sound, radio or other frequencies, there are a number of known parameters that can be varied in order to perceptibly or imperceptibly convey embedded messages. Frequency modulated radio transmissions are an example where the frequency of a carrier wave is altered in pace with speech or music and which variation is later retrievable as the original message. Amplitude, phase and pulse are other examples of parameters that can be so varied. The intended message can then be further concealed by various methods of encryption.

In the case of the referenced U.S. Pat. No. 6,330,672, a key may accompany the message as an indicative of a certain mark or marks which have been hidden inside the original message, a virtual watermark, thereby making it possible to reveal the source or identity of the digital material so marked.

A problem to be solved is thus to provide a method and an apparatus for encoding digital information which both provide an unique new original while making this encoding virtually impossible to find by a fraudulent person.

### SUMMARY OF THE INVENTION

An object of the present invention is to provide a method and an apparatus for rendering works unique in such a way that each and any digital representation treated in accordance with the invention may be identified while making this identification virtually impossible to find by a fraudulent person.

The invention is based on the realization that the hardest thing to find is something which is not there. Making use of this realization, the current invention processes any digital material in such a way to rendering it unique as an original and imperceptibly encoding a message by way of removing objects or tiny fractions of objects, fractions of wave forms or bits from the original material. By removing should be understood actual removal in time of information, not merely replacing existing information with other information.

According to the invention there is provided a method of encoding digital representations of works comprising the steps of providing a digital representation of a work, and removing pieces of information from said digital representation in a predetermined pattern.

There is also provided a method of decoding digital representations of works comprising the following steps: synchronizing a customer original digital representation of a work with a true original digital representation of a work, identifying a first piece of information missing in said customer original digital representation as compared with said true original digital representation, recording an identification of said first piece of information missing; and identifying and recording second and further pieces of information missing in said customer original digital representation by repeating the identifying and recording steps.

There is also provided an apparatus for performing encoding of digital representations of works comprising: means for providing a digital representation of a work, and means for removing pieces of information from said digital representation in a predetermined pattern.

There is also provided an apparatus for decoding digital representations of works comprising: means for synchronizing a customer original digital representation of a work with a true original digital representation of a work, means for identifying a first, second and further pieces of information missing in said customer original digital representation as compared with said true original digital representation, and means for recording an identification of said first, second, and further pieces of information missing.

With the inventive methods and apparatus the above-mentioned drawbacks of prior art are eliminated or at least mitigated. The method provides for an identification of digital representations which is virtually impossible to locate and remove.

In a particularly preferred embodiment, the predetermined pattern is repeated, making removal thereof from an illegal copy virtually impossible.

Further preferred features are defined in the dependent claims.

### BRIEF DESCRIPTION OF DRAWINGS

The invention is now described, by way of a non-limiting example, with reference to the accompanying drawings, in which:

FIG. 1 shows two wave forms that are identical but which have no coinciding points due to a slight offset of time on one of the wave forms.

FIG. 2 shows a number of random objects.

FIG. 3 shows a musical wave form where a tiny fraction has been cut out.

FIGS. 4A and 4B are flow charts describing the essential workflow of an exemplary embodiment of the invention.

FIG. 5 is a flow chart showing the encoding process according to the present invention.

FIG. 6 illustrates how a missing sampling is equalized by standard decoding techniques.

FIGS. 7A-D show an example of a simplified pattern and how it is matched while mining proper identification data from an absence coded digital representation.

FIG. 8 illustrates a wave form where extraneous information has been added.

FIG. 9 shows the phasing of two wave forms.

FIG. 10 is a diagram explaining the absence coding principles.

FIG. 11 is a flow chart describing the basic absence coding detection.

FIG. 12 is an overall diagram of an apparatus for performing the inventive method.

### DETAILED DESCRIPTION OF THE INVENTION

In the following a detailed description of preferred embodiments of the present invention will be given. This invention presents an effective variant of how the digital representation of any copyrighted material or works can be imperceptibly altered in order to render the representation unique and identifiable. In order to embed a message or identification into a digital representation, it is usually necessary to add or superimpose the desired information onto the original material. More or less sophisticated methods can then be used in order to retrieve the information at a later stage. Using any such method, the original material would then be intact, whether encrypted or not, together with the additional information. Someone who intends to steal the material would then need to restore the material to an unencrypted state as well as remove the identity information. According to the principles of the present invention, the most effective way of protecting digital works in this context is first of all to render the material to be distributed unique in such a way that no two “copies” are the same but all representations of a material are unique as virtual originals. In the following, the expression “true original” will be used to denote the original that is encoded to create a “customer originnal”, which is the information that is distributed to customers. All originals can be provided in any convenient form, such as a computer file.

Also, in the present description the word “work” will be used. Although a music piece will be used as an example, it will be appreciated that this word also encompasses other kinds of information, such as video recordings, text information etc. It should also be noted that digitized work in this context refers to any work, whether originally in analogue or digital form, which is represented by a bit stream or sampling of the original material whether previously processed by other software or devices or not.

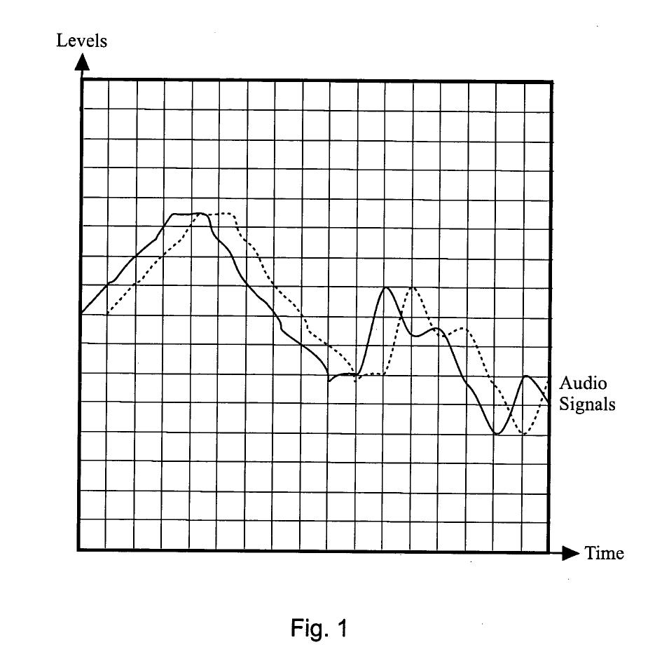

Using a music piece as an example to illustrate this first principle, this step can be accomplished for instance by altering the phase of the music. FIG. 1 shows two wave forms that are identical but which have no coinciding points due to a slight offset of time on one of the wave forms. In the example, the difference between the forms is easily detectable and the illustration is made only for the purpose of making the underlying principle understandable.

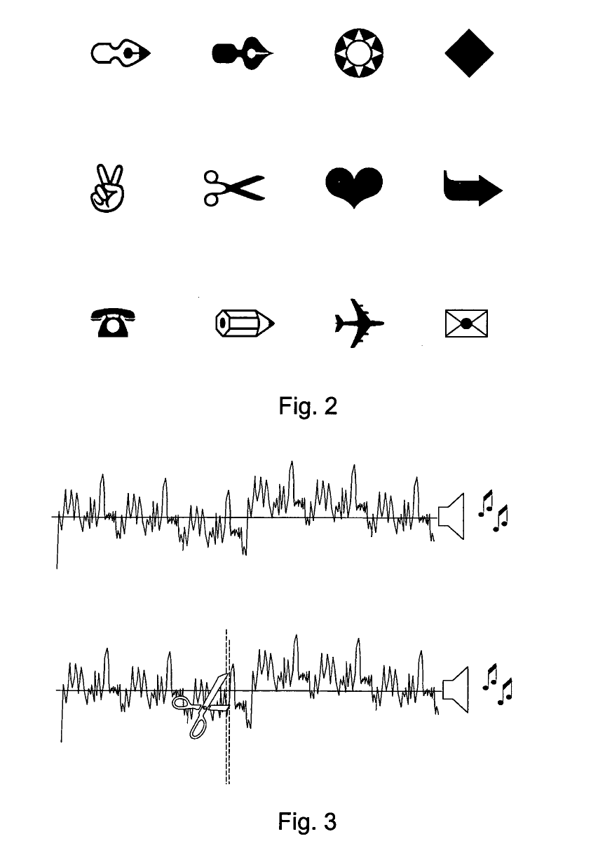

The second important principle of the present invention is the fact that, unless there is a useful reference, the hardest thing to find is something which is not there. FIG. 2 shows a number of random objects. It is impossible, just by looking at FIG. 2 to determine if the number of objects is correct or if they are the right objects. Making use of these principles, the current invention processes any digital material in such a way to render it unique as a customer original and imperceptibly encoding a message by way of removing objects or tiny fractions of objects, fractions of wave forms or bits from the original material.

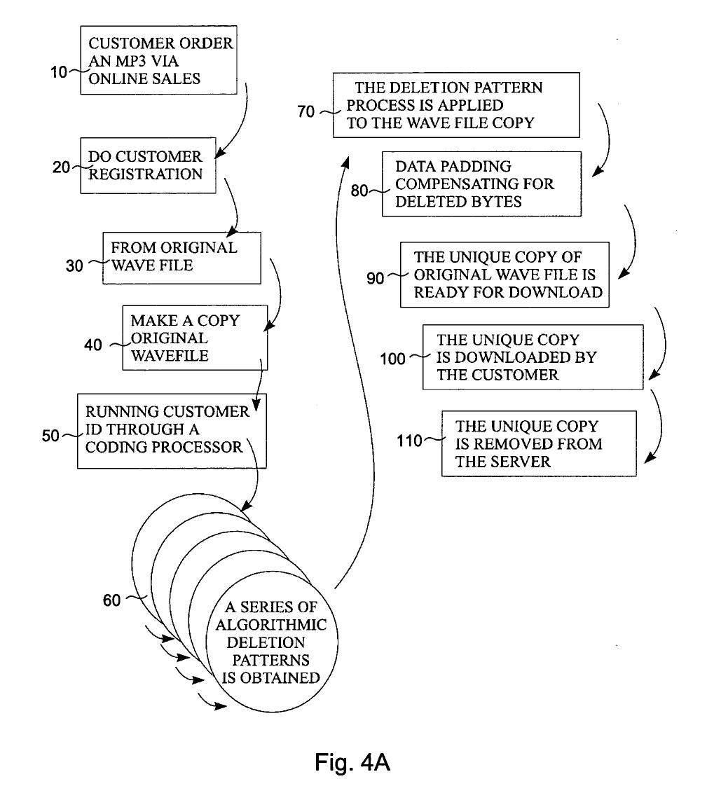

The basic principles of the invention is further illustrated by FIG. 3 which shows a musical wave form where a tiny fraction has been cut out, which in FIG. 3 is equivalent to a missing sampling. Due to the standard techniques used in decoding, for example music encoded with MP3 compression, the missing sampling can not be detected in the resulting music output.

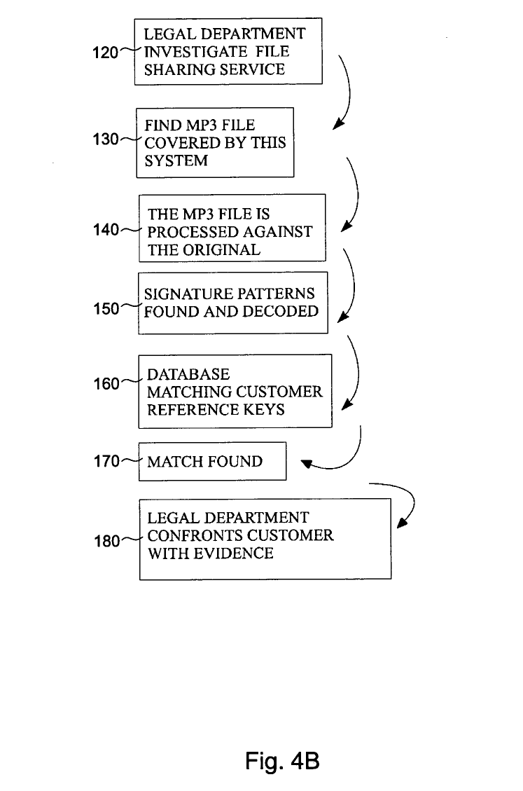

FIG. 4A is a flow diagram which describes the essential encoding workflow of an exemplary embodiment of the invention. In step 10, a customer orders a digital work, such as a music file, via online sales on e.g. the Internet. The customer has to register himself or herself, step 20. During the registration process information for identifying the customer must be given.

After the registration process, the true original is retrieved, step 30, and a copy wave file is made from the true original, step 40. The provision of a customer original involves running the customer ID through a coding processor, step 50, whereby a series of algorithmic deletion patterns is obtained, step 60. In step 70, the deletion pattern process is applied to the customer wave file where after data padding compensating for deleted bytes is performed in step 80. The unique customer original which is a modified copy of the true original is then ready for downloading in step 90. When the customer has downloaded his or her original in step 100, this file is optionally removed from the server in step 110

FIG. 4B is a flow diagram which describes the essential decoding workflow of an exemplary embodiment of the invention. When a possibly illegal copy of a work has been found, a legal department investigating file sharing services is consulted in step 120. The content of the possibly illegal copy, such as a particular song, is identified in step 130. The possibly illegal copy is then processed against the true original in step 140 and the signature patterns are found and decoded in step 150. A database matching is performed in step 160, wherein the ID of registered customers are used. When a match is found in step 170, the legal department confronts the identified customer with evidence in step 180.

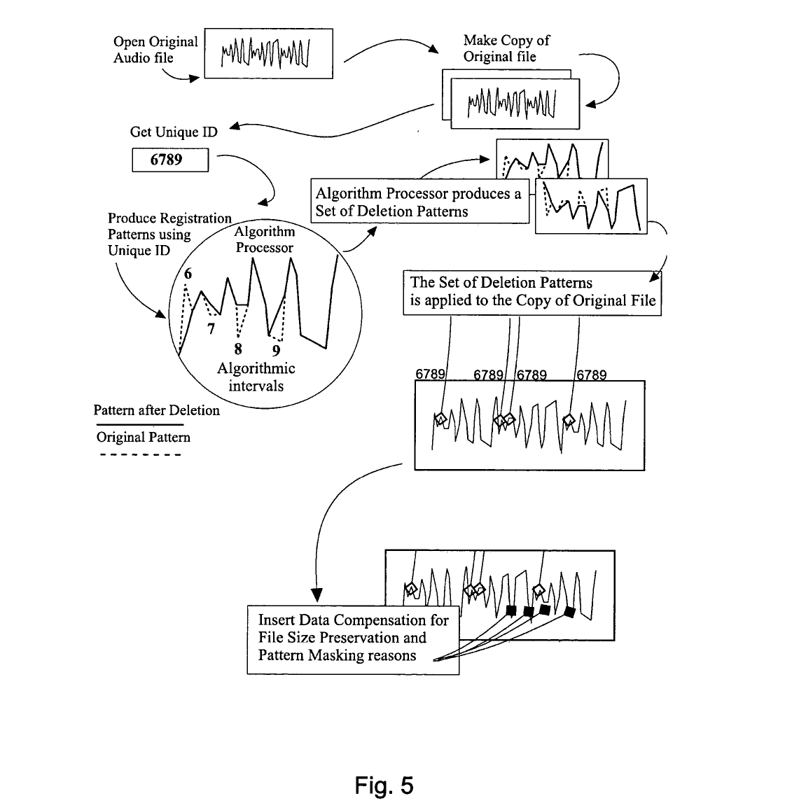

Essential for the workability of the present invention is that the device utilized for the absence encoding according to the invention has a processing module or processor which imperceptibly alters the true original in such a way that each customer original so produced becomes a unique and identifiable copy or virtual new original. Steps 30-80 of FIG. 4A are exemplified in FIG. 5, showing the encoding process.

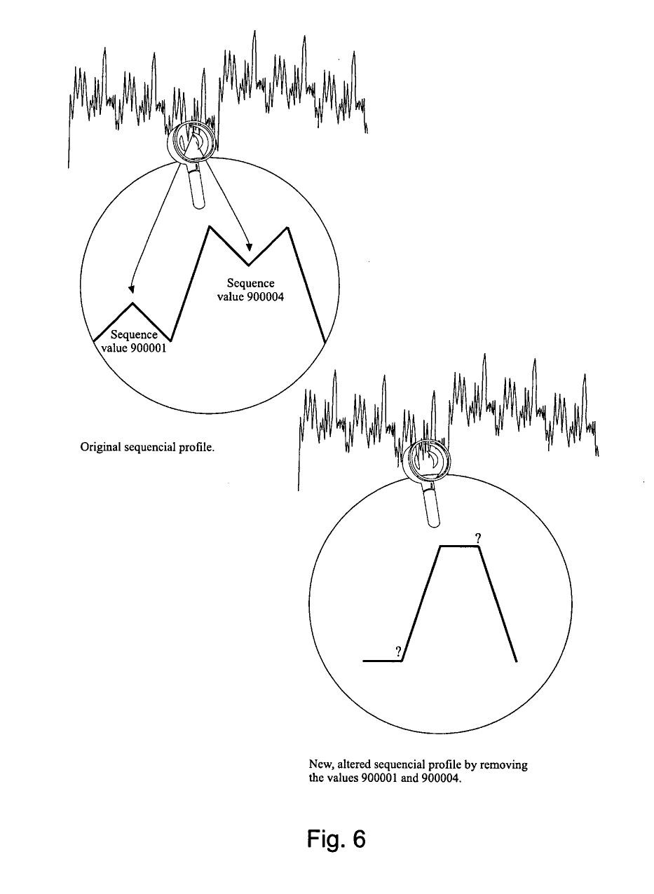

FIG. 6 illustrates how a missing sampling is equalized by standard decoding techniques. One of the main purposes of the technique employed by the present innovation is thus to make it possible to imperceptibly code a message into any digital bit stream or any sampled wave form as distinct from hitherto utilized and patented techniques which utilize perceptual coding.

To the upper left in the figure there is shown the original sequential profile. The sequence values 900001 and 900004 are marked as two pieces of information that are to be removed in the encoding process. The encoding algorithm ensures that the removal of the information does not degrade the quality of the encoded work in a perceptual way. Also, the algorithm may also be adapted not to remove a piece of information with identical value as an adjacent piece of information to ensure that decoding will be possible.

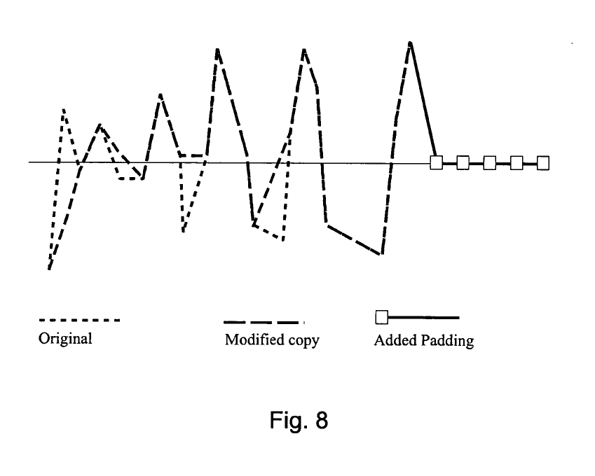

With sequence values 900001 and 900004 removed, the encoded profile will look as is shown to the lower right in FIG. 4. The encoded profile is shorter than the original sequence. This is corrected by means of padding, as will be described below with reference to FIG. 8.

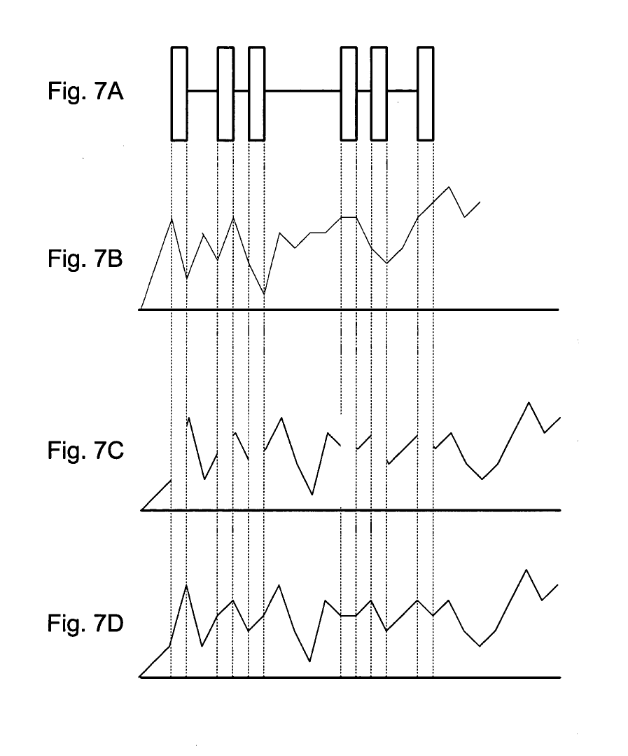

The invention also considers the possibility that someone bent on illegal distribution may further alter the digital work in order to cut out or disguise the origin of the work or any inherent identity information. To prevent such occurrence the invention prescribes a repetition of the absence encoding in such a way as to constitute a pattern, exemplified in FIG. 7A, which is visually or audibly imperceptible to the end user during playback of the material. This pattern can take any suitable form, i.e., there can be one or several successive deletions of samples, the distance between deleted samples can vary etc.

While it is recognized that recurring patterns is a lead in to the decoding of any coded message, the patterns introduced by the present invention is much less vulnerable to detection as they consists of elements which are not there. Again, it is extremely hard to detect something which is not there unless one knows that it should be there. Through the use of patterns, the present invention makes it virtually impossible to cut out or alter parts of the work being protected in order to destroy the identifiable originality of the material. The deletion thus ensures that the pattern can be found even though a fraudulent owner removes part of the information. As an example, the deletion pattern can be introduced ten times in a wave file of a music work with a duration of three minutes.

The wave form of the customer original is shown in FIG. 7B. Padding to compensate for gaps is not shown. When expanding the customer original wave form by applying the deletion pattern in FIG. 7A on this wave form, the wave form shown in FIG. 7C is obtained, showing the absence gaps. This can be compared with the true original wave form shown in FIG. 7D.

Although the number of distinct patterns used while implementing the present invention is not limited and can consist of anything between one and millions of patterns, it is suggested for the practicability of the implementation, that the number of patterns is kept manageable, perhaps in the order of a hundred. The patterns which preferably are distributed throughout the audio, video, or bit stream, serve several purposes. They prevent intentional distortion of the information content for the purposes of masking or destroying the inherent identity information while they also, together with a check sum figure, serve to validate the imperceptibly coded absence information.

In order to prevent that the described patterns open doors to alter the originality of a media file for example by comparing several different files in order to obtain information by mapping differences, wave form fragments or extraneous information may preferably be added in order to pad the length of a file, a segment of a file or a bit count. Any extraneous information so added and exemplified in FIG. 8 does not contain any information and relates to the present invention only as a means of disguising the positioning of elements belonging to the absence coding.

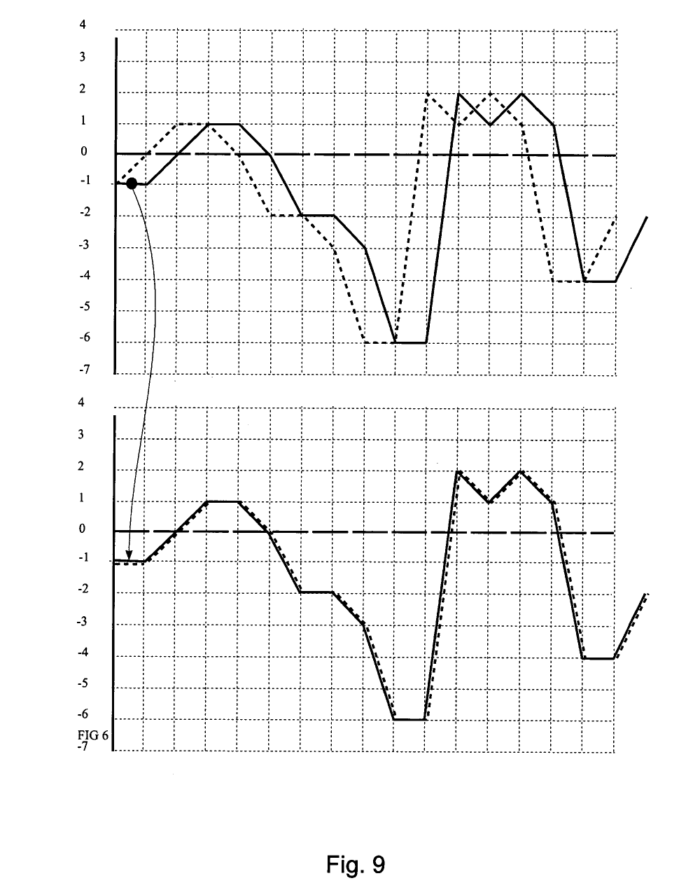

FIG. 9 shows the restoration of an absence encoded wave file shown in dashed lines by the insertion of a previously deleted sample. Thereby the absence encoded wave file will correspond to the original wave file shown in continuous lines.

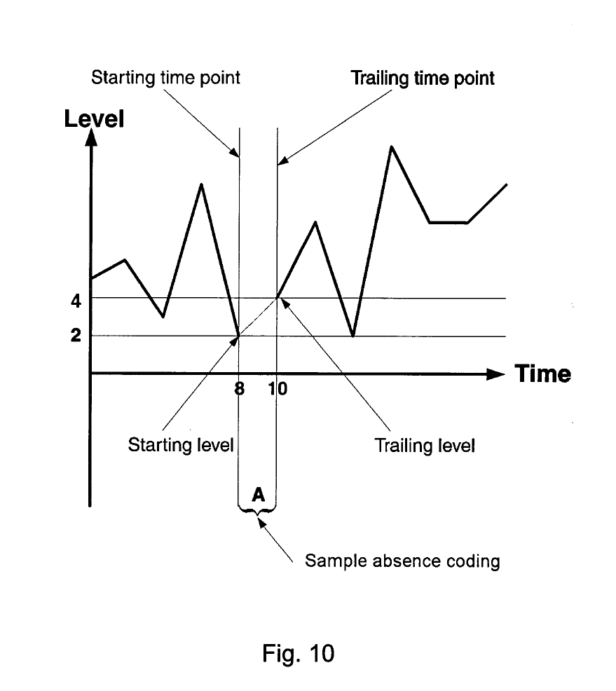

The absence coding principles will be further explained in the following with reference to FIG. 10. The first signal absence is detected by synchronization and comparison with the true original. When an absence is found the coded reference segment is retrieved by utilization of either of:
the starting level of the absence, or
the trailing level of the absence, or
the starting time of the absence, or
the trailing time of the absence, or
the level of the omitted segment in the true original, or
any combination of the above.

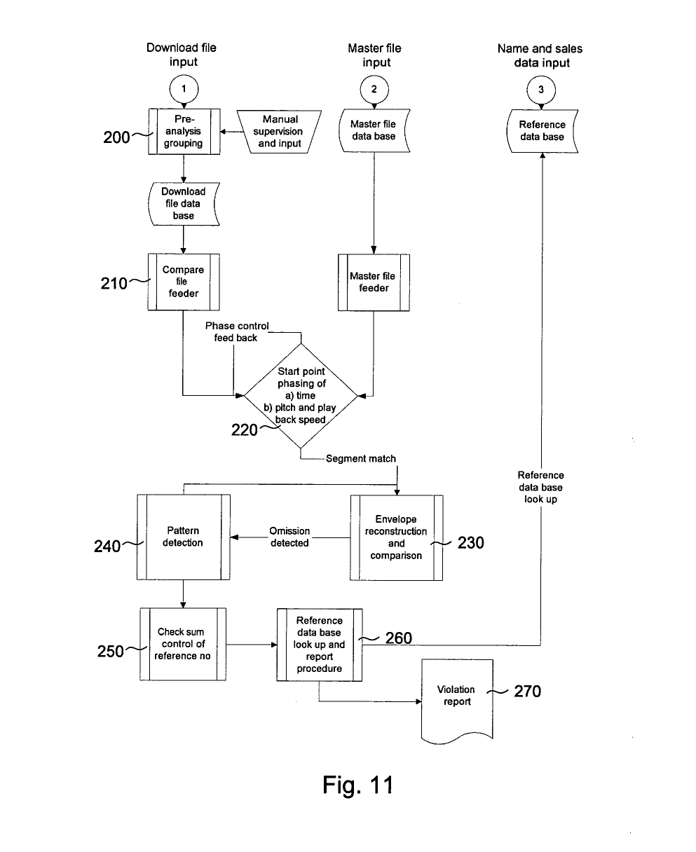

A decoding process according to the invention will now be described with reference to FIG. 11. In step 200, a pre-analysis is done of the files to be checked for identity. The purpose of the pre-analysis is to group e.g. music files into categories in order to lower the amount of files that will have to be cross checked against each other. Files may be grouped according to length, as well as a number of other characteristics, such as beat.

In step 210, the comparison of a file against a master file, starts with a phasing of the files in step 220 against each other in order to determine a common starting point where the wave form of the file to be compared, closely matches a segment of the master file. This initial phasing is done by taking time as well as playback speed into consideration. The purpose of this step is to enable identification also of files which have been distorted, whether on purpose or not.

In step 230, when a close match has been found between a segment of the master file and corresponding segment of the file to be compared (the compare file), envelop reconstruction is done in order to restore the compare file to its original status and eliminate losses caused by prior compression in the distribution chain. Coded absences in the compare file are differentiated and are not restored at this point in time.

An absence code detection is performed in step 240. From step 230 above, the compare file has been restored to be almost identical to the master file. Any difference is part of the potential absence coding of that file. When such an absence is detected, the detection process automatically goes on high alert and switches to pattern detection. This signifies that subsequent absences must follow the initial absence according to one of a number of predetermined patterns. Each absence detected in the compare file is checked to find if it is part of one of the predetermined patterns or not.

When a pattern match has occurred the previous steps are looped throughout the file. When a pattern match occurs, the coded reference number is retrieved according to the basic principles shown in FIG. 10.

Step 250 is a verification step. The check sum of the reference number retrieved in step 240 is calculated in order to determine that the reference number is valid. If it is found to be valid, a data base look-up is done in step 260 in order to find the identity corresponding to the reference number.

Provided that the reference number in step 250 checked out and a valid identity could be retrieved from the data base, an identity report is written out or is otherwise presented in step 270. In the case of comparison of files suspected of copyright violations, the report, as in FIG. 11, is a violation report.

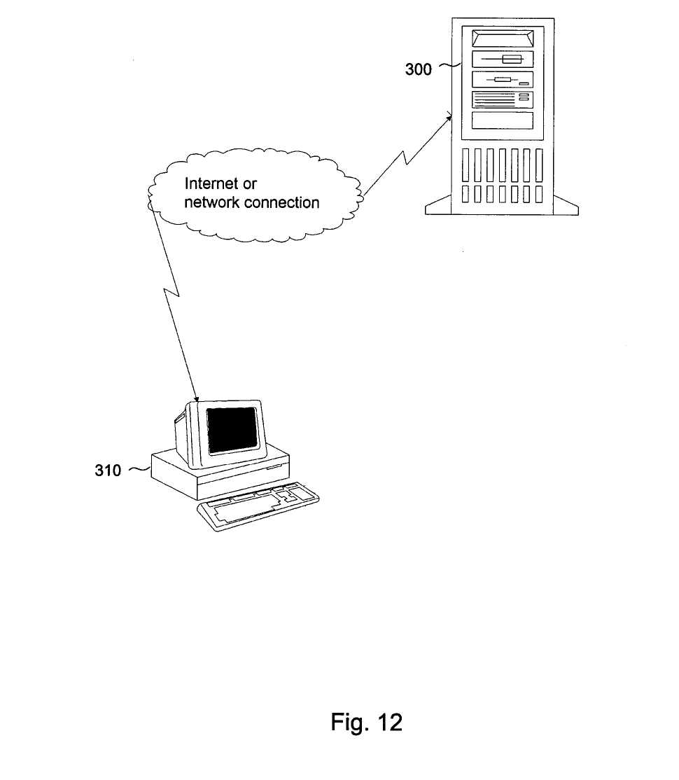

An overall diagram of an apparatus for performing the inventive method is shown in FIG. 12. A computer 300 having the hardware necessary for performing the required calculations is used. The computer is preferably connected to a computer network, such as the Internet. The same network can be used by a number of users, one of which is represented by a computer 310 in the figure, for downloading works protected with the method according to the invention.

A preferred embodiment of a method and an apparatus for encoding digital representations of works according to the invention have been described. The person skilled in the art realises that this could be varied within the scope of the appended claims.

Digital sampling of a work has been described as part of the inventive method. It will be appreciated that both constant and variable bit rate sampling are feasible.

Downloading over the Internet has been described as a way of distributing digital representations of works protected by absence encoding. It will be appreciated that digital representations of works distributed through other channels, such as music shops etc., can be protected by means of absence coding. In that case, each digital representation distributed this way is uniquely coded and this unique code is noted at the time of selling the digital representation. For example, the customer is asked to identify himself or herself at the time of purchase and the identity is associated with the unique code in a register. Alternatively or additionally the identity of the work, such as the name of the record and/or the artist, could be encoded into the digital representation of the work so as to enable identification thereof if a manipulated illegal copy is found.

The present invention makes no claims as to the content of the actual message or data being coded. For practical purposes it may be convenient to adapt the original work being processed in accordance with the invention in such a way that the missing fragments indicate a specific number with a check sum figure which points to a certain record in a central data base.

1. A method of encoding digital representations of works comprising the following steps:
a) providing a digital representation of a work, and
b) removing pieces of information from said digital representation in a predetermined pattern.

2. The method according to claim 1, wherein said pieces of information comprise digital samples.

3. The method according to claim 1, wherein said predetermined pattern is repeated.

4. The method according to claim 1, wherein said work is a digital representation of any of the following; audio information, image information, and text information.

5. The method according to claim 1, comprising the additional step of inserting padding information after the step of removing pieces of information.

6. The method according to claim 1, comprising the steps of:
ordering said work by a customer;
identification by said customer;
retrieving a true original digital representation of said work;
making a customer original digital representation of said work which is identical to said true original digital representation;
removing pieces of information from said customer original digital representation in a predetermined pattern;
providing said customer with said customer original digital representation.

7. A method of decoding digital representations of works comprising the following steps:
a) synchronizing a customer original digital representation of a work with a true original digital representation of a work,
b) identifying a first piece of information missing in said customer original digital representation as compared with said true original digital representation,
c) recording an identification of said first piece of information missing;
d) identifying and recording second and further pieces of information missing in said customer original digital representation by repeating steps b) and c) above.

8. The method according to claim 7, comprising the additional step of making a pre-analysis of said customer original digital representation for identity before the step of synchronizing.

9. The method according to claim 7, comprising the additional step of envelope reconstruction before the step of identifying a first piece of information missing in order to restore the customer original digital representation caused by prior compression.

10. The method according to claim 7, comprising the additional step of enhancing the transparency of a distorted customer original with the true original digital representation of a work,

11. The method according to claim 7, comprising the additional step of verifying the encoding by means of a check sum.

12. An apparatus for performing encoding of digital representations of works comprising:
means for providing a digital representation of a work, and
means for removing pieces of information from said digital representation in a predetermined pattern.

13. An apparatus for decoding digital representations of works comprising:
means for synchronizing a customer original digital representation of a work with a true original digital representation of a work,
means for identifying a first, second and further pieces of information missing in said customer original digital representation as compared with said true original digital representation, and
means for recording an identification of said first, second, and further pieces of information missing.
